(19) United States
(12) Patent Application Publication
(10) Pub. No.: US 2007/0068796 A1
(43) Pub. Date: Mar. 29, 2007

(54) METHOD OF USING A TARGET HAVING END OF SERVICE LIFE DETECTION CAPABILITY

(75) Inventors: Yi-Li Hsiao, Hsinchu City (TW); Chen-Hua Yu, Hsin-Chu (TW); Jean Wang, Hsin Chu (TW); Lawrance Sheu, Hsinchu City (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd., Hsin-Chu (TW)

(21) Appl. No.: 11/463,406

(22) Filed: Aug. 9, 2006

Related U.S. Application Data
(63) Continuation-in-part of application No. 11/427,602, filed on Jun. 29, 2006.
Application No. 11/427,602 is a continuation-in-part of application No. 11/427,618, filed on Jun. 29, 2006.
(60) Provisional application No. 60/720,390, filed on Sep. 26, 2005.
(60) Provisional application No. 60/728,724, filed on Oct. 20, 2005.
(60) Provisional application No. 60/736,389, filed on Nov. 14, 2005.

(51) Int. Cl. C23C 14/32; C23C 14/00

(52) U.S. Cl. 204/192.1; 204/298.12

(57) ABSTRACT

A method and system for detecting a lifetime of a slab of consumable material used by a process tool. In the method and system, the slab of consumable material is provided with at least one indicator. A determination is made as to whether a value of a signal generated by a detector associated with the at least one indicator during operation of the process tool is equal to a warning setting value, is between the warning setting value and an alarm setting value, is equal to an alarm setting value, or is above the alarm setting value. A first warning is provided if the value of the signal is equal to the warning setting value or between the warning setting value and the alarm setting value, the first warning indicating that the slab of consumable material is approaching a predetermined quantity which is less than an original quantity of the slab of consumable material. A second warning is provided if the value of the signal is between the warning setting value and the alarm setting value, the second warning indicating that the slab of consumable material is approaching the predetermined quantity. An alarm is provided if the value of the signal is equal to the alarm setting value or above the alarm setting value, the alarm indicating that the slab of consumable material is approaching the predetermined quantity or has been reduced to the predetermined quantity.

### RELATED APPLICATIONS

This application claims the benefit of U.S. Provisional Application Ser. No. 60/736,389, filed on Nov. 14, 2005, U.S. Provisional Application No. 60/720,390, filed Sep. 26, 2005 and U.S. Provisional Application No. 60/728,724, filed Oct. 20, 2005, the entire disclosures of which are incorporated herein by reference, and is a continuation-in-part of U.S. patent application Ser. No. 11/427,602, filed on Jun. 29, 2006 and a continuation-in-part of U.S. patent application Ser. No. 11/427,618, filed on Jun. 29, 2006, the entire disclosures of which are incorporated herein by reference.

### FIELD OF THE INVENTION

The invention relates to material deposition. More particularly, the invention relates to methods using target end of service life detection capability.

### BACKGROUND OF THE INVENTION

Physical vapor deposition (PVD) is a well known process for depositing a thin film of material on a substrate and is commonly used in the fabrication of semiconductor devices. The PVD process is carried out at high vacuum in a chamber containing a substrate (e.g., wafer) and a solid source or slab of the material to be deposited on the substrate, i.e., a PVD target. In the PVD process, the PVD target is physically converted from a solid into a vapor. The vapor of the target material is transported from the PVD target to the substrate where it is condensed on the substrate as a thin film.

There are many methods for accomplishing PVD including evaporation, e-beam evaporation, plasma spray deposition, and sputtering. Presently, sputtering is the most frequently used method for accomplishing PVD. During sputtering, a gas plasma is created in the chamber and directed to the PVD target. The plasma physically dislodges or erodes (sputters) atoms or molecules from the reaction surface of the PVD target into a vapor of the target material, as a result of collision with high-energy particles (ions) of the plasma. The vapor of sputtered atoms or molecules of the target material is transported to the substrate through a region of reduced pressure and condenses on the substrate, forming the thin film of the target material.

PVD targets have finite service lifetimes. PVD target overuse, i.e., use beyond the PVD target's service lifetime, raises reliability and safety concerns. For example, PVD target overuse can result in perforation of the PVD target and system arcing. This, in turn, may result in significant production losses, PVD system or tool damage and safety problems.

The service lifetime of a PVD target is presently determined by tracking the accumulated energy, e.g., the number of kilowatt-hours (kw-hrs), consumed by the PVD system or processing tool. The accumulated energy method, however, takes time to master and the accuracy of this method depends solely on the hands-on experience of the technician. Even when mastered, the service lifetimes of the PVD targets are still less than they could be, as approximately 20-40 percent of the PVD target (depending upon the PVD target type) is wasted.

The low target utilization resulting from the PVD targets' abbreviated service lifetimes, creates high PVD target consumption costs. In fact, PVD target consumption cost is one of the most significant costs in semiconductor fabrication. Thus, if much of the wasted target material could be utilized, PVD target consumption costs could be substantially reduced. This, in turn, would significantly lower semiconductor fabrication costs and increase profitability.

The low target utilization also results in more frequent replacement of the PVD target and, therefore, more frequent maintenance of the PVD system or tool. Further, when the PVD target is replaced, time is needed to retune the PVD process for the new target.

Accordingly, a method using target end of service life detection capability is needed.

### SUMMARY

A system and method are described for detecting a lifetime of a slab of consumable material used by a process tool. In the system and method, the slab of consumable material is provided with at least one detector or indicator. It is then determined whether a value of a signal generated by a detector associated with the at least one indicator during operation of the process tool is equal to a warning setting value, is between the warning setting value and an alarm setting value, is equal to an alarm setting value, or is above the alarm setting value. A first warning is provided if the value of the signal is equal to the warning setting value or between the warning setting value and the alarm setting value, the first warning indicating that the slab of consumable material is approaching a predetermined quantity which is less than an original quantity of the slab of consumable material. A second warning is provided if the value of the signal is between the warning setting value and the alarm setting value, the second warning indicating that the slab of consumable material is approaching the predetermined quantity. An alarm is provided if the value of the signal is equal to the alarm setting value or above the alarm setting value, the alarm indicating that the slab of consumable material is approaching the predetermined quantity or has been reduced to the predetermined quantity.

### BRIEF DESCRIPTION OF THE DRAWINGS

FIG. 1A is a cross-sectional view illustrating an exemplary embodiment of a target having end of service life detection capability.

FIG. 1B is a plan view of an exemplary embodiment of a target having a plurality of end of service life indicators.

FIG. 2 is a block diagram depicting an exemplary embodiment of a wafer processing system which uses a target having one or more end of service life indicators.

FIG. 3 is a schematic diagram of an exemplary embodiment of a process chamber where a target having end of service life detection capability may be used.

FIG. 4 is a flow chart illustrating the steps of an exemplary method for controlling a gas detector and process tool in the automatic system communication framework.

FIG. 5 is a graph plotting one embodiment of gas detector signal values versus time.

### DETAILED DESCRIPTION OF THE INVENTION

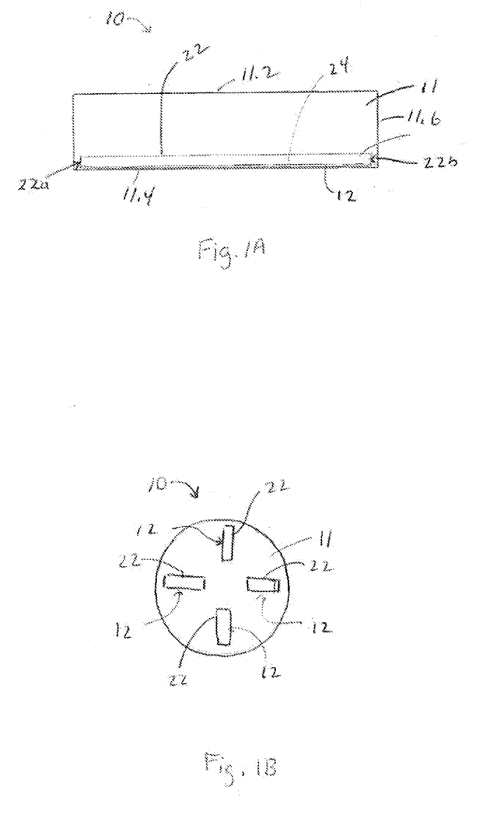

A system and method of detecting an end of service life of a target or other consumable material, is disclosed herein. The target may be of a type which is used as a source material in a material deposition process, such as physical vapor deposition (PVD). FIG. 1A is a cross-sectional view illustrating an exemplary embodiment of a target having end of service life detection capability, denoted by numeral 10. The target 10 comprises a slab 11 of a consumable material (target slab) and one or more end of service life detectors or indicators 12 which are capable of indicating that the target slab 11 is soon approaching and/or has been reduced to a predetermined quantity.

The target slab 11 comprises a reaction surface 11.2, a base surface 11.4 opposite the reaction surface 11.2 and a sidewall surface 11.6 extending between the reaction surface 11.2 with the base surface 11.4. The target slab 11 may be formed in any suitable and appropriate shape including, for example, circular, square, rectangular, oval, triangular, irregular, etc. The target slab 11, in one embodiment, may have a diameter (in the case of a circular slab) of 12 inches and a thickness of 0.250 inches. In other embodiments, the target slab 11 may be formed to other suitable and appropriate dimensions. The target slab 11 may be composed of any suitable and appropriate source material including, for example, nickel, nickel platinum alloys, nickel titanium alloys, cobalt, aluminum, copper, titanium, tantalum, tungsten, ITO, ZnS—SiO₂.

In one exemplary embodiment, the one or more indicators 12 may each comprise a gas indicator which is partially or totally embedded in the base surface 11.4 of the target slab 11. It should be understood, however, that the one or more indicators 12 may also comprise other types of indicators (e.g., filament, electrode, and/or second material indicators) which are capable of indicating that the target slab 11 is soon approaching and/or has been reduced to a predetermined quantity. If more than one indicator 12 is used, the indicators 12 are generally equi-spaced across the target slab 11 to increase detection resolution, as shown in the plan view of FIG. 1B.

Referring to FIGS. 1A and 1B, each of the gas indicators 12, in one exemplary embodiment, may comprise a tube or enclosure 22 having opposing open ends 22a, 22b. In one exemplary embodiment, the tube 22 may be composed of the same material as the target slab 11. The open ends 22a, 22b of the tube 22 may be closed and hermetically sealed by closures (not shown). The tube 22 is filled with an inert gas 24, such as helium, krypton, etc., which does not affect the material deposition processing result. In other embodiments, the tube 22 may also be filled with or contain a liquid or a solid which is capable being detected when released from the tube 22. Other embodiments of the target and indicator and methods for making such targets and indicators are described in detail in U.S. patent application Ser. No. 11/427,602, filed on Jun. 29, 2006, and U.S. patent application Ser. No. 11/427,618, filed on Jun. 29, 2006, the entire disclosures of which have been incorporated herein by reference.

The diameter of the tube 12 should be sufficiently small so that it is not exposed until nearly all the target slab 11 has been consumed. In one exemplary embodiment, the tube 22 may have a diameter of about 0.5 mm.

The target slab 11 is eroded or consumed by process forces, e.g., the sputtering plasma, during processing in the process chamber. As long as the tube(s) 22 of the indicator(s) 12 remains un-breached, the inert gas 24 will remain undisturbed therein. When erosion and consumption of the target slab 11 causes the tube(s) 22 of the indicator(s) 12 embedded in the target slab 11 to become exposed and then breached by the process forces, the tube(s) 22 of the indicator(s) 12 will begin to emit or leak the inert gas 24 contained therein, into the process chamber, thereby providing a detectable signal which indicates that the target 10 is soon approaching its service lifetime endpoint. Such an indication may be used to adjust and/or limit the number of lots of wafers or the like that will be processed further on with that particular target 10.

Continued processing with the target 10 will eventually erode or consume the target slab 11 and tube(s) 22 to the point where additional emission or leakage of the inert gas (e.g., from the tubes 22 of the other indicators 12) and/or accelerated emission or leakage of the inert gas (e.g., from further erosion of the tube(s) 22) into the process chamber will take place, thereby providing a detectable signal which indicates that the service lifetime endpoint of the target 10 has been reached. This indication may be used to further adjust, and/or further limit the number of lots of wafers or the like that will be processed further on with that particular target, or to stop the process chamber altogether and replace the target with another (new) target.

In one embodiment, the end of service life (EOL) detection capability provided by the one or more indicators 12 enables the target slab 11 to be reduced to a residual quantity less than 0.5 percent of the original quantity of the slab material. This, in turn, optimizes target utilization, reduces target costs, increases the length of preventative maintenance cycles, shortens process tuning time, and increases the utilization rate of associated production tools and process chambers.

The target 10 may used in material deposition processes, such as PVD, without significant hardware modifications and/or changes. Further, the target 10 may be used in different types of magnetic systems including magnetron systems, capacitively coupled plasma (CCP) systems, and inductively coupled plasma (ICP) systems, to name a few. The target 10 may also be used in all types of power supply systems including, without limitation, direct current power systems, alternating current power systems, and radio frequency power systems.

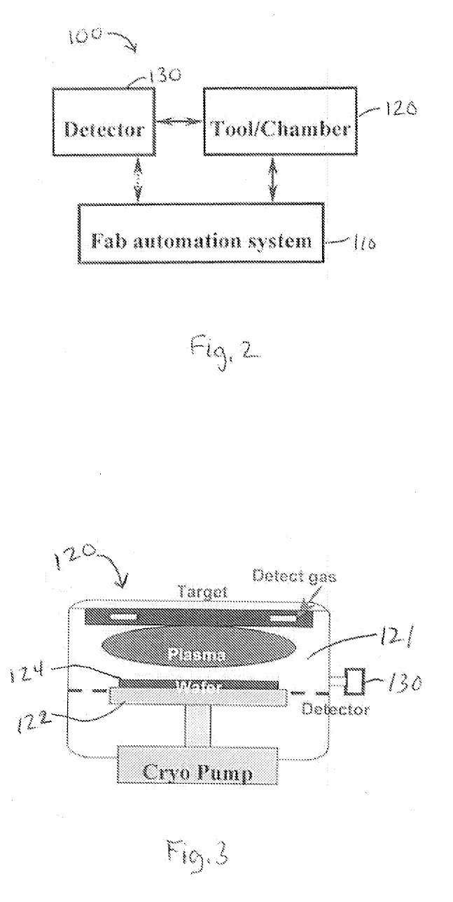

FIG. 2 is a block diagram depicting an exemplary embodiment of a wafer processing system 100 which uses a target having one or more indicators. The system 100 comprises a fabrication automation system 110 including a computer, a process tool 120, e.g., a wafer process chamber, and a computer controlled monitoring device 130, which in the case of the gas type indicator 12 illustrated herein, detects or monitors gas emission from the tube(s) 22 of the indicator(s) 12.

As shown in FIG. 3, the process chamber 120 comprises an interior 121 and a wafer stage 122 disposed within the interior 121 for supporting a wafer 124 to be processed. The target 10 of the invention may be mounted above the wafer stage 122 in the interior 121 of the process chamber 120. The gas detecting/monitoring device (gas detector) 130 may be mounted outside the process chamber 120 in manner which allows it to detect and/or monitor the emission of the inert gas 24 into the interior 121 of the chamber 120. The gas detector 130 may comprise, for example, an optical emission spectrometer (OES), or a residual gas analyzer (RGA). Alternatively, the gas detector 130 may comprise a pressure monitoring device (GP) that measures the pressure of the inert gas 24 within the tube 22 of the indicator 12. During processing, the gas detector 130 generates a range of detector values in response to the quantity of inert gas emitted by the one or more indicators 12 of the target 10.

As illustrated in FIG. 2, an automatic system communication framework or network is utilized in the wafer processing system 100 by providing two-way communication between the fabrication automation system 110 and the gas detector 130, two-way communication between the fabrication automation system 110 and the process chamber 120, and two-way communication between the gas detector 130 and the process chamber 120. The automatic system communication framework allows the gas detector 130, which detects and monitors gas emission from the one or more indicators 12 of the target 10, to be used to automatically control the number of semiconductor wafer lots or lots of items or materials to be processed, which will be processed in the process chamber 120 with a given target 10, thereby optimizing target utilization, reducing target costs, increasing the length of preventative maintenance cycles, shortening process tuning time, and increasing the utilization rate of the process chamber 120. For example, “one wafer lot” may be defined as a predetermined number of wafers to be processed in a single carrier or cassette wherein the maximum number of wafers in one wafer lot may be 25 wafers.

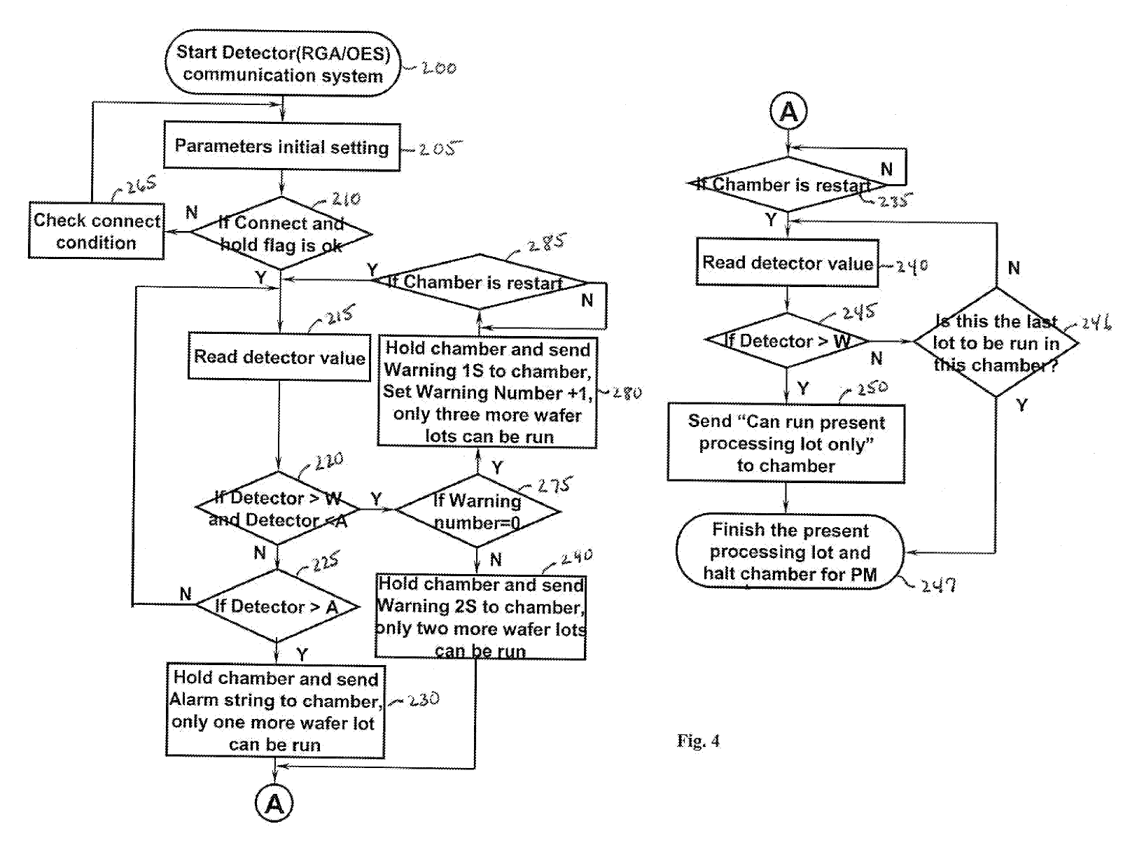

FIG. 4 is a flow chart illustrating the steps of an exemplary method for controlling the gas detector 130 and the chamber/tool 120 in the automatic system communication framework. The control method is performed by the computer of the fabrication automation system and may be implemented conventionally, for example, as a software program. The method commences in step 200 by starting the gas detector 130 in the automatic system communication framework. In step 205, certain parameters of the gas detector 130 are initially set. In one exemplary embodiment, the initial settings of the gas detector parameters may include:
a connect flag is set to 1 (where 1=enable and 0=disable);
a warning number set to a number 0 (wherein the number can be 0, 1, and 2);
a counter number set to 4, (or a number greater than 3 wafer lots);
an alarm flag set to 0 (where 1=enable and 0=disable);
an initial gas detector/inert gas background setting value B, which may be an inputted or a default setting;
a gas detector/inert gas warning setting value W, which may be an inputted or a default setting;
a gas detector/inert gas alarm setting value A, which may be an inputted or a default setting;
a message sent to chamber/tool for first warning, such as 1S, which refers to a “first target warning”;
a message sent to chamber/tool for second warning, such as 2S, which refers to a “second target warning”;
a message sent to chamber/tool for alarm, such as A, which refers to a “target alarm.”

In response to the appropriate signal from the gas detector (when the gas detector detects certain quantities of the inert gas emitted from the tube of the indicator), the computer of the fabrication automation system 110 sends the corresponding one of the above messages to the process chamber/tool and halts the process chamber/tool for further processing.

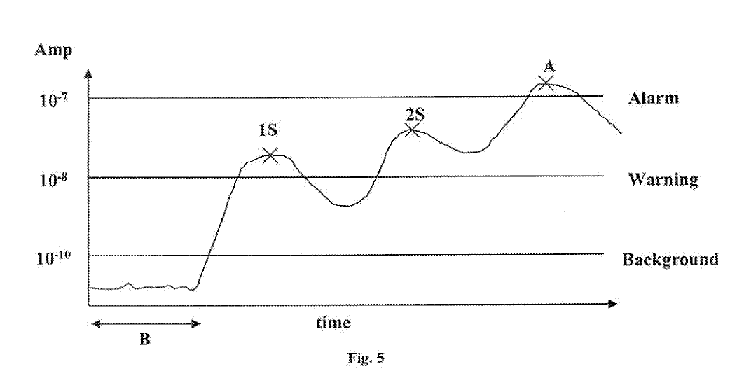

FIG. 5 is a graph plotting one embodiment of gas detector signal values, which correspond to quantities of inert gas detected, versus time. It should be understood that other embodiments of gas detector signal values versus time are contemplated. As illustrated, the gas detector signal value for the inert gas background setting may be value B, the gas detector signal value for the inert gas warning setting may be value W, and the gas detector signal value for the inert gas alarm setting may be value A. At the beginning of the process (shown with period B), there is no emission of the inert gas, e.g. krypton, from the indicator tube and therefore, the signal value detected is below the background signal value, for example 10⁻¹¹ amps. After a period of processing, such as 2600 Kw-hr, the target is consumed and the inert gas is emitted from the tube of the indicator. When the emission of the inert gas exceeds the warning setting, for example, when the gas detector signal value is 10⁻⁸ amps, the gas detector sends a first warning signal, such as 1S, to the chamber/tool. When the emission of the inert gas exceeds the warning setting for the second time, the gas detector sends a second warning signal, such as 2S, to the chamber/tool. When the emission of the inert gas exceeds the alarm setting, for example, when the gas detector signal value is 10⁻⁷ amps, the gas detector sends an alarm signal, such as A, to the chamber/tool.

In one embodiment, when the first warning signal (1S) is sent, chamber/tool processing is halted after processing of the current wafer lot and a counter associated with the computer of the fabrication automation system 110 is triggered whereby the initial parameter setting of greater than 3 (using the above example of initial parameters settings) is set to a default setting of 3 wafer lots. The first warning indicates that 3 wafer lots may be processed going forward with the current (residual) target. When the second warning signal (2S) is sent, chamber/tool processing will be halted (after the current wafer lot is processed) and the second warning indicates that 2 wafer lots may be processed going forward with the current residual target. When the alarm signal (A) is sent, chamber/tool processing is halted (after the current wafer lot is processed) and the alarm indicates that 1 wafer lot may be processed going forward with the current residual target.

Referring again to FIG. 4, in step 210 of the method, it is determined whether the connect and alarm flag settings are correct. If the connect and alarm flags settings are not correct, then the connect and alarm flags are checked in step 265 and set again in step 205. If the connect and alarm flags settings are correct, then the gas detector value is read in step 215.

In general, the gas detector value will be below the background setting value B if the tube(s) 22 of the target indicator 12 remain un-breached by the process forces. When erosion and consumption of the target slab 11 causes the tube(s) 22 of the indicator(s) 12 to become exposed and then breached by the process forces, the tube(s) 22 of the indicator(s) 12 will begin emitting the inert gas 24 contained therein, into the process chamber 120. The gas detector 130 will detect inert gas emission into the process chamber 120 and generate detector values generally above the background setting value B. Finally, the gas detector values will extend to and even surpass the alarm setting value A, depending upon the quantity of inert gas emitted into the process chamber 120.

In step 220, a determination is made as to whether the gas detector value read in step 215 is between the inert gas warning setting value W and the inert gas alarm setting value A. If the gas detector value is between the inert gas warning setting value W and the inert gas alarm setting value A, then in step 275 a determination is made as to whether the warning number is equal to 0.

If the warning number in step 275 is equal to 0, then processing in the process chamber 120 is halted in step 280 so that the “first target warning” message may be sent to the process chamber 120 and the warning number can be set to 1. The “first target warning” message in step 280 triggers a counter whereby the initial parameter setting of greater than 3 is set to a default setting of 3 wafer lots, which indicates the number N1 of residual wafer lots, for example, 3 wafer lots, that can be processed going forward with the current residual target 10. Then in step 285 a determination is made as to whether the process chamber 120 has been checked and then re-started by an engineer or technician. This step ensures that the engineer/technician takes notice of the status of warning (i.e., the indication associated with the warning in terms of the number of residual wafer lots which may be processed going forward) and personally checks this status. Then, the engineer/technician releases the halting status of the process chamber and the process chamber is re-started for processing. If the process chamber has been re-started, then the method returns to the gas detector value read step 215. If the process chamber 120 has not been re-started, then the method loops back to the process chamber re-start determination step 285 wherein a determination is made as to whether the process chamber 120 has been checked and re-started by an engineer or technician. The counter of the residual number N1 of wafer lots for processing after step 285 is then decreased by 1 after completion of the current wafer lot.

Returning to step 275 again, if the warning number is not equal to 0, then processing in the process chamber 120 is halted in step 290 so that the “second target warning” message can be sent to the process chamber 120. The warning number is not equal to 0, and the number must be 1. The “second target warning” message indicates the number of wafer lots, for example 2 wafer lots, to be processed going forward with the current residual target 10. The number of residual wafer lots for processing in step 290 is compared to the counter number N1 of residual wafer lots for processing after step 285. The smaller of the two numbers will be updated to be the counter and this number of residual wafer lots will be processed in step 290. Then in step 235 a determination is made as to whether the process chamber 120 has been checked and re-started by an engineer or technician.

Returning to step 220, if the gas detector value read in step 215 is not between the inert gas warning setting value W and the inert gas alarm setting value A, then it is determined in step 225 whether the gas detector value read in step 215 is above the inert gas alarm setting value A. If the gas detector value in step 215 is not above the inert gas alarm setting value A, then steps 215, 220, etc. are performed again. If, however, the gas detector value read in step 215 is above the inert gas alarm setting value A, then the processing in the process chamber 120 is halted in step 230 so that the “Alarm” message can be sent to the process chamber 120. The “Alarm” message indicates that the number of residual wafer lots, for example 1 lot, to be processed going forward with the current target. The number of residual wafer lots for processing in step 230 is compared to the counter number N1 of residual wafer lots for processing after step 285 (or this counter is equal to 4 now, as it is not triggered yet.). The smaller of the two numbers will be updated to the counter and this number of residual wafer lots will be processed in step 230. Then in step 235, a determination is made as to whether the process chamber 120 has been checked and re-started by an engineer or technician.

If the process chamber 120 has been re-started in step 235, then the detector value is read in step 240. If the process chamber 120 has not been re-started, then the method loops back to the process chamber re-start determination step 235 wherein a determination is made as to whether the process chamber 120 has been checked and re-started by an engineer or technician.

In step 240, the gas detector value is read and in step 245 a determination is made as to whether the gas detector value in step 240 is above the inert gas warning setting value W. If the gas detector value in step 245 is not above the inert gas warning setting value W, then it is determined in step 246 whether the lot being process is the last lot for processing in chamber 120, which means the counter number N1 of residual wafer is equal to 0. If lot being process is the last lot in step 246, then the method goes to step 247 to complete processing of the present lot and to halt chamber for preventative maintenance. If the currently running lot is not the last lot in step 246, then the method returns to step 240.

If the gas detector value in step 245 is above the inert gas warning setting value W, a “can run present processing lot only” message is sent to the process chamber 120 in step 250. This indicates that only the present lot may be processed going forward with the current target. At this moment of step 250, the counter number N1 of residual wafer lot is automatically set to 0. After the completion of step 250, the method moves to step 247 to complete the present processing lot and halt chamber for preventative maintenance. The process chamber 120 is stopped by the tool automation system 120 and/or the fabrication automation system 110.

While the foregoing invention has been described with reference to the above, various modifications and changes can be made without departing from the spirit of the invention. Accordingly, all such modifications and changes are considered to be within the scope of the appended claims.

What is claimed is:

1. A system comprising:
a process tool;
a slab of consumable material used by the process tool;
at least one indicator in the slab associated with the slab of consumable material;
a detector associated with the at least one indicator; and
a computer communicating with the detector to allow detection of a condition in which the slab of consumable material is approaching or has approached a predetermined quantity which is less than an original quantity of the slab of consumable material.

2. The system of claim 1, wherein the computer determines whether a value of a signal generated by the detector during operation of the process tool, is equal to a warning setting value, between the warning setting value and an alarm setting value, equal to an alarm setting value, or above the alarm setting value; and provides a first warning if the value of the signal is equal to the warning setting value or between the warning setting value and the alarm setting value, the first warning indicating that the slab of consumable material is approaching the predetermined quantity which is less than the original quantity of the slab of consumable material.

3. The system of claim 2, wherein the computer communicates with the process tool and halts the operation of the process tool if the first warning is provided.

4. The system of claim 2, wherein the computer provides an alarm if the value of the signal is equal to the alarm setting value or above the alarm setting value, the alarm indicating that the slab of consumable material is approaching the predetermined quantity or has been reduced to the predetermined quantity.

5. The system of claim 4, wherein the computer communicates with the process tool and halts the operation of the process tool if the alarm is provided.

6. The system of claim 2, wherein the computer provides a second warning if the value of the signal is between the warning setting value and the alarm setting value, the second warning indicating that the slab of consumable material is approaching the predetermined quantity.

7. The system of claim 6, wherein the computer communicates with the process tool and halts the operation of the process tool if the second warning is provided.

8. The system of claim 6, wherein the computer provides an alarm if the value of the signal is equal to the alarm setting value or above the alarm setting value, the alarm indicating that the slab of consumable material is approaching the predetermined quantity or has been reduced to the predetermined quantity.

9. The system of claim 8, wherein computer communicates with the process tool and halts the operation of the process tool if the alarm is provided.

10. The system of claim 1, wherein the slab of consumable material comprises a physical vapor deposition target.

11. The system of claim 1, wherein the at least one indicator comprises:
an enclosure at least partially embedded within the slab of consumable material; and
one of a filament element and electrode elements, disposed within the enclosure.

12. The system of claim 11, wherein the enclosure is composed of the consumable material.

13. The system of claim 1, wherein the at least one indicator comprises:
an enclosure at least partially embedded within the slab of consumable material; and
one of a gas, a liquid, and a solid disposed within the enclosure.

14. The system of claim 13, wherein the one of the gas, the liquid, and the solid is capable being detected by the detector when released from the enclosure.

15. The system of claim 1, wherein the computer communicates with the process tool.

16. A method of detecting a lifetime of a slab of consumable material used by a process tool, the method comprising the steps of:
providing the slab of consumable material with at least one indicator;
determining whether a value of a signal generated by a detector associated with the at least one indicator during operation of the process tool, is equal to a warning setting value, between the warning setting value and an alarm setting value, equal to an alarm setting value, or above the alarm setting value; and
providing a first warning if the value of the signal is equal to the warning setting value or between the warning setting value and the alarm setting value, the first warning indicating that the slab of consumable material is approaching a predetermined quantity which is less than an original quantity of the slab of consumable material.

17. The method of claim 16, wherein the operation of the process tool is halted if the first warning is provided.

18. The method of claim 17, further comprising the step of reducing a number of item lots to be further processed by the process tool using the slab of consumable material.

19. The method of claim 16, further comprising the step of reducing a number of item lots to be further processed by the process tool using the slab of consumable material.

20. The method of claim 16, further comprising the step of providing an alarm if the value of the signal is equal to the alarm setting value or above the alarm setting value, the alarm indicating that the slab of consumable material is approaching the predetermined quantity or has been reduced to the predetermined quantity.

21. The method of claim 20, wherein the operation of the process tool is halted if the alarm is provided.

22. The method of claim 21, further comprising the step of reducing a number of item lots to be further processed by the process tool using the slab of consumable material.

23. The method of claim 22, wherein the number of item lots to be further processed is less than a number of item lots to be further processed if the first alarm is provided by the process tool using the slab of consumable material.

24. The method of claim 20, further comprising the step of reducing a number of item lots to be further processed by the process tool using the slab of consumable material.

25. The method of claim 24, wherein the number of item lots to be further processed is less than a number of item lots to be further processed if the first alarm is provided by the process tool using the slab of consumable material.

26. The method of claim 16, further comprising the step of providing a second warning if the value of the signal is between the warning setting value and the alarm setting value, the second warning indicating that the slab of consumable material is approaching the predetermined quantity.

27. The method of claim 26, wherein the operation of the process tool is halted if the second warning is provided.

28. The method of claim 27, further comprising the step of reducing a number of item lots to be further processed by the process tool using the slab of consumable material.

29. The method of claim 28, wherein the number of item lots to be further processed is less than a number of item lots to be further processed if the first alarm is provided by the process tool using the slab of consumable material.

30. The method of claim 26, further comprising the step of reducing a number of item lots to be further processed by the process tool using the slab of consumable material.

31. The method of claim 30, wherein the number of item lots to be further processed is less than a number of item lots to be further processed if the first alarm is provided by the process tool using the slab of consumable material.

32. The method of claim 26, further comprising the step of providing an alarm if the value of the signal is equal to the alarm setting value or above the alarm setting value, the alarm indicating that the slab of consumable material is approaching the predetermined quantity or has been reduced to the predetermined quantity.

33. The method of claim 32, wherein the operation of the process tool is halted if the alarm is provided.

34. The method of claim 33, further comprising the step of reducing a number of item lots to be further processed by the process tool using the slab of consumable material.

35. The method of claim 34, wherein the number of item lots to be further processed is less than a number of item lots to be further processed if the second alarm is provided by the process tool using the slab of consumable material.

36. The method of claim 32, further comprising the step of reducing a number of item lots to be further processed by the process tool using the slab of consumable material.

37. The method of claim 36, wherein the number of item lots to be further processed is less than a number of item lots to be further processed if the second alarm is provided by the process tool using the slab of consumable material.

38. The method of claim 16, wherein the slab of consumable material comprises a physical vapor deposition target.

39. The method of claim 16, wherein the at least one indicator comprises:
an enclosure at least partially embedded within the slab of consumable material; and
one of a filament element and electrode elements, disposed within the enclosure.

40. The method of claim 39, wherein the enclosure is composed of the consumable material.

41. The method of claim 16, wherein the at least one indicator comprises:
an enclosure at least partially embedded within the slab of consumable material; and
one of a gas, a liquid, and a solid disposed within the enclosure.

42. The method of claim 41, wherein the one of the gas, the liquid, and the solid is capable being detected by the detector when released from the enclosure.
